(19) United States
(12) Patent Application Publication
(10) Pub. No.: US 2006/0160382 A1
(43) Pub. Date: Jul. 20, 2006

(54) Electronic apparatus including connector terminal

(75) Inventors: Kazufumi Nishida, Echizen-city (JP); Shin'ichi Aoyama, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/327,509

(22) Filed: Jan. 9, 2006

(30) Foreign Application Priority Data
Jan. 18, 2005 (JP) 2005-010073

(51) Int. Cl. H05K 1/00

(52) U.S. Cl. 439/76.1

(57) ABSTRACT

On connection of a control board and an external apparatus, an externally connecting cable which is drawn out from a rear surface of the casing can be drawn out without interfering with other components. A connector terminal 32 which connects the external apparatus is mounted to be inclined with respect to a control board 30 mounted substantially vertically in a cabinet 5, and is mounted along an inclined surface 13A formed in a downward direction in a stepped recessed part 13 of a back cabinet 5B. Thereby, a cable 31 which is connected to the connector terminal 32 does not interfere with a cover portion 13C of the stepped recessed part 13, which covers a support column part 17 of a stand 15.

The present application is based on and claims priority of Japanese patent application No. 2005-010073 filed on Jan. 18, 2005, the entire contents of which are hereby incorporated by reference.

### BACKGROUND OF THE INVENTION

1. Field of the Invention

The present invention relates to an electronic apparatus including a connector terminal, in which a connector terminal mounted on a control board is fitted to a rear surface of a casing so as to connect an external cable via the connector terminal.

2. Description of the Related Art

An electronic apparatus such as a television receiving set generally includes various kinds of input and output terminals, and connects an external apparatus to these input and output terminals to input or output signals, and on connection with the external apparatus, a connector terminal of the input and output terminal is conventionally mounted on a control board which is housed in a casing of a television receiving set or the like, and a connecting connector of an external connecting cable connected to the external apparatus is connected to the connector terminals.

Incidentally, in recent years, various kinds of thin display units such as a liquid crystal panel and a plasma display are developed in television receiving sets, and when a cable or the like for connecting to an outside is connected to the connector terminal mounted on a control board as described above in the television receiving sets mounted with such thin display units, if the cable is drawn out substantially perpendicularly with respect to the rear surface of a casing, an excess space for drawing out the cable or the like is required at the rear surface of the casing, therefore, making it impossible to obtain an advantage of space saving by reduction in thickness. Thus, for example, Japanese Patent Laid-Open Publication No. 6-267601 (patent document 1) proposes, in a control device constructed by an electric component, a print board mounted on the electric component, and a heat release fin intended to cool the heat-producing component, a control device in which a mounting position at which a connector that is mounted to the control device and is for interfacing with an external device is mounted is formed to be diagonal with a predetermined angle with respect to the mounting surface of the control device.

According to the control device shown in the patent document 1, an inclined surface inclined downward is formed from a lower portion of a front surface panel of a box-shaped control box to a lower surface panel, and a connector terminal is mounted to the inclined surface, whereby connection of the connector terminal and a communication connector is facilitated, and since the communication connector and the communication cable do not project forward from the front surface of the control box when they are connected, a front surface space of the control box can be effectively utilized, in addition to which, reduction of a control panel housed in the control box and space saving are realized. However, in the patent document 1, a concrete structure is not described concerning the mounting structure of the connector terminal mounted to the inclined surface of the control box to the control board provided in the control box, and is unclear, but a connector terminal b for connecting to an external connector is generally mounted on a control substrate a. In a liquid crystal television receiving set or the like, the connector terminal b which is mounted on the control board a is mounted so that a connecting portion b1 of the connector terminal b is horizontal to the control board a as shown in FIG. 7A, or the connector terminal b is mounted so that the connecting portion b1 of the connector terminal b is orthogonal to the control board a as shown in FIG. 7B. Therefore, when the connecting portion b1 of the connector terminal b is mounted horizontally with respect to the control board a in the control device shown in the patent document, if the connector b is mounted to an inclined surface 101 of a control box 100 as shown in FIG. 8A, the control board a is disposed to be parallel with the inclined surface 101, and therefore, a width w of the control board a is limited, thus making it impossible to house the large-sized control substrate a in the control box 100. On the other hand, when the connecting portion b1 of the connector terminal b is mounted perpendicularly to the control board a, it is necessary to mount the control board a to be inclined in the control box 100 as shown in FIG. 8B, and therefore, a mounting space for the control board a in the control box increases, thus making it difficult to downsize the device. Especially, in an electronic apparatus which is required to be thin such as a liquid crystal television receiving set, a structure capable of housing the control board in the casing compactly and compactly drawing out a cable or the like which is drawn out from the rear surface of the casing is desirable.

### SUMMARY OF THE INVENTION

The present invention is made in view of the above described problem, and has an object to provide an electronic apparatus including a connector terminal which compactly houses a control board in a casing, and is capable of compactly drawing out an externally connecting cable drawn out of the rear surface of the casing without interfering with the other components on connection of the control board and an external apparatus, in a liquid crystal television receiving set or the like.

An electronic apparatus including a connector terminal according to a first aspect of the present invention includes, in an electronic apparatus in which various kinds of electronic components and a control board that controls the electronic components are housed inside a casing, a connector terminal connected to the control board is fixed to face an opening formed on a rear surface of the casing, and a connecting connector of an externally connecting cable is connected to the connector terminal, at least an inclined surface with a downward inclination which is formed on the rear surface, and has the construction in which the opening is formed in the inclined surface, the cable which is connected to the connector terminal fitted to the opening via the connecting connector is guided to be drawn out diagonally rearward in a downward direction, the control board is fixed substantially parallel with respect to the rear surface, and the connector terminal which is mounted to the control board is mounted to be inclined with respect to the control board corresponding to an inclination angle of the inclined surface.

According to the above described construction, the connector terminal for connecting the cable of the external apparatus is mounted at an inclination angle of the inclined surface formed in the downward direction, and therefore, when the cable of the external apparatus is connected to the connector terminal, the cable is drawn out substantially vertically with respect to the inclination surface and drawn out in the state inclined in the downward direction, thus making it unnecessary to secure a useless space to draw out the cable to the rear side of the casing. While the control board is mounted substantially vertically in the casing, the connector terminal for connecting the cable of the external apparatus is mounted to be inclined with respect to the control board corresponding to the inclination angle of the inclination surface, and therefore, the control board is compactly housed in the casing, and it is not necessary to secure a wide space for mounting the control board in the casing.

The electronic apparatus including a connector terminal according to a second aspect has, in the electronic apparatus including a connector terminal according to the first aspect, the construction in which a housing of the connecting connector is bent in a lateral direction so that the cable which is drawn out of the connecting connector is drawn out to a side portion of the casing.

According to the above described construction, the connector housing of the connecting connector is bent toward an outside, and therefore, the cable which is led out of the connecting connector is drawn out to a side of the cabinet, thus facilitating routing of the cable.

The electronic apparatus including a connector terminal according to third or forth aspect has, in the electronic apparatus including a connector terminal according to the first or second aspect, the construction in which the casing is constituted of a front cabinet and a back cabinet, a display unit is housed in the casing, a stand which supports the casing is provided, a mounting bracket which extends downward is fixed to the display unit, and the mounting bracket is fixed to a support bracket which is rotatably attached to the stand.

According to the above described construction, an angle of the display unit is made adjustable by inclining the display unit fitted to the stand in the longitudinal direction.

The electronic apparatus including a connector terminal according to a fifth or sixth aspect has, in the electronic apparatus including a connector terminal according to the third or fourth aspect, the construction in which a stepped recessed part which includes an inclined surface to which the connector terminal is fitted and a bottom portion is formed at a rear surface of the back cabinet, and a cover portion which covers the stand is provided extensively from the bottom portion of the stepped recessed part to be opposed to the inclined surface, and the inclination angle of the inclined surface is set so that the cable drawn out of the inclined surface does not interfere with the cover portion.

According to the above described construction, the angle of the inclined surface is set so that the cable and the cover portion do not interfere with each other, and therefore, stress such as bending stress is not exerted on a joint portion of the connector terminal and the connecting connector and the cable.

The electronic apparatus including a connector terminal according to a seventh, eighth, ninth or tenth aspect has, in the electronic apparatus including a connector terminal according to the third, fourth, fifth or sixth aspect, the construction in which a space in which the support bracket is capable of being inserted is formed between the mounting bracket and the bottom portion of the stepped recessed part, the mounting bracket and the support bracket are fixed with a screw, and an open hole through which the fixing screw is capable of inserted is formed at the bottom portion of the stepped recessed part.

According to the above described construction, the bottom portion of the stepped recessed part and the mounting bracket are in close vicinity with each other, and when the fixing screw which fixes the support bracket and the mounting bracket is inserted from the open hole formed at the bottom portion, the positions of the insertion hole of the mounting bracket through which the fixing screw is inserted and the screw hole of the support bracket can be directly recognized from the outside of the back cabinet, and the connecting connector is fixed by utilizing the stepped recessed part, whereby, it is not necessary to form a mounting part for fitting the connecting connector separately at the back cabinet 5B.

### BRIEF DESCRIPTION OF THE DRAWINGS

FIG. 1 is an enlarged sectional view showing a fixed state of a support bracket showing embodiment 1 of the present invention;

FIG. 2 is an enlarged sectional view showing a fixed state of a mounting bracket of the same;

FIG. 3 is a rear view of the fixed state of the support bracket and the mounting bracket of the same;

FIG. 4 is a rear view of a cabinet of the same;

FIG. 5 is a rear view of the cabinet with a back cabinet removed of the same;

FIG. 6 is a rear view of a cabinet showing embodiment 2 of the present invention;

FIG. 7 is a perspective view showing a conventional connector terminal, FIG. 7A shows a connector terminal with a connecting part formed horizontally with respect to a control board, and FIG. 7B shows the connector terminal with the connecting part formed vertically with respect to the control board; and

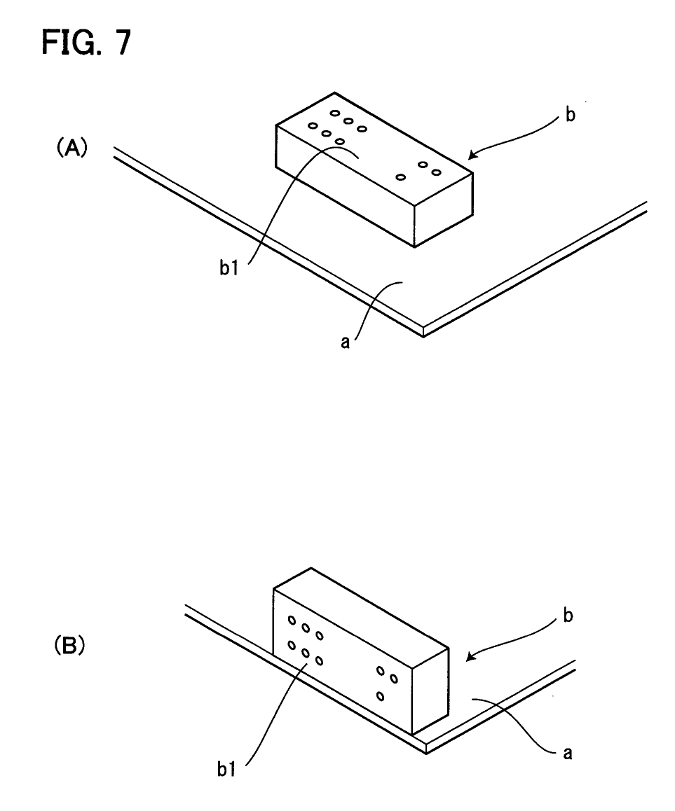

FIG. 8 is an explanatory view showing a state in which a cable is connected to the connector terminal of the same, FIG. 8A shows the case where the connector terminal with the connecting part formed horizontally with respect to the control board is housed in a control box, and FIG. 8B shows the case where the connector terminal with the connecting part formed vertically with respect to the control board is housed in the control box.

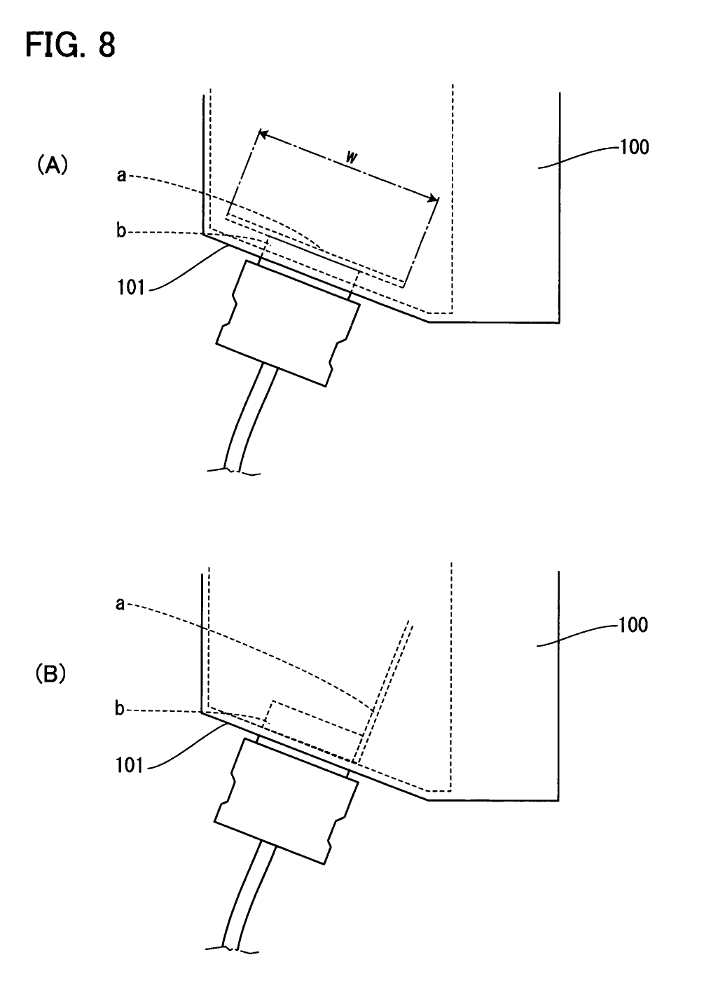

### DETAILED DESCRIPTION OF THE PREFERRED EMBODIMENTS

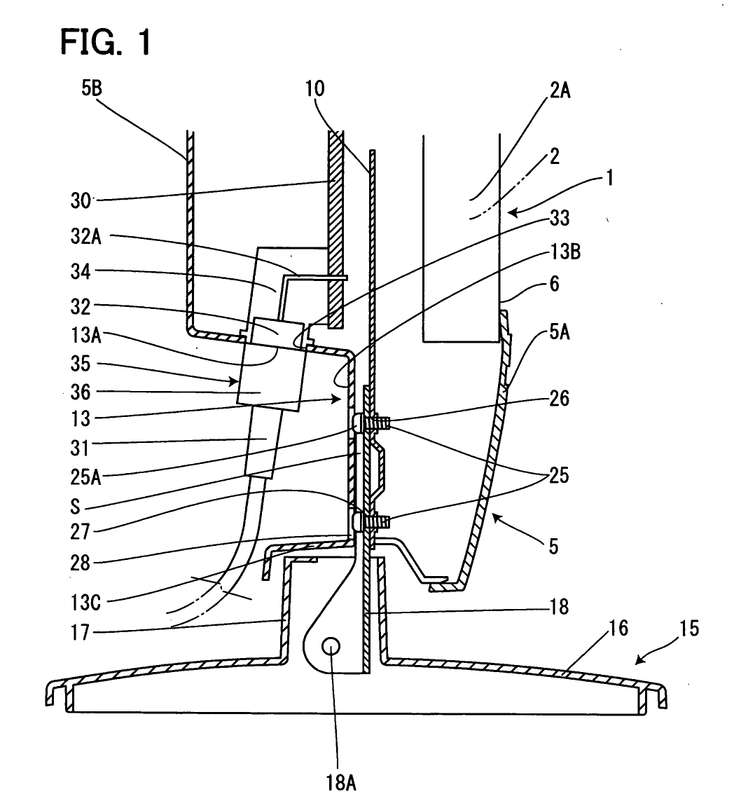

Hereinafter, embodiments as the best mode for carrying out the present invention will be described with reference to FIG. 1 to FIG. 5. It goes without explaining that the present invention is easily applicable to those except for the apparatus explained in the embodiments.

### Embodiment 1

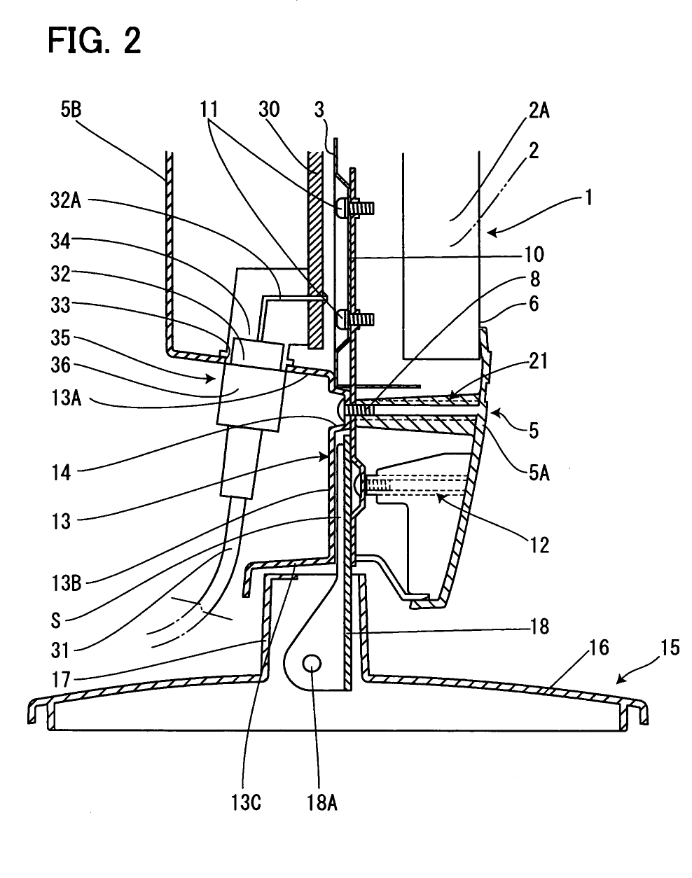

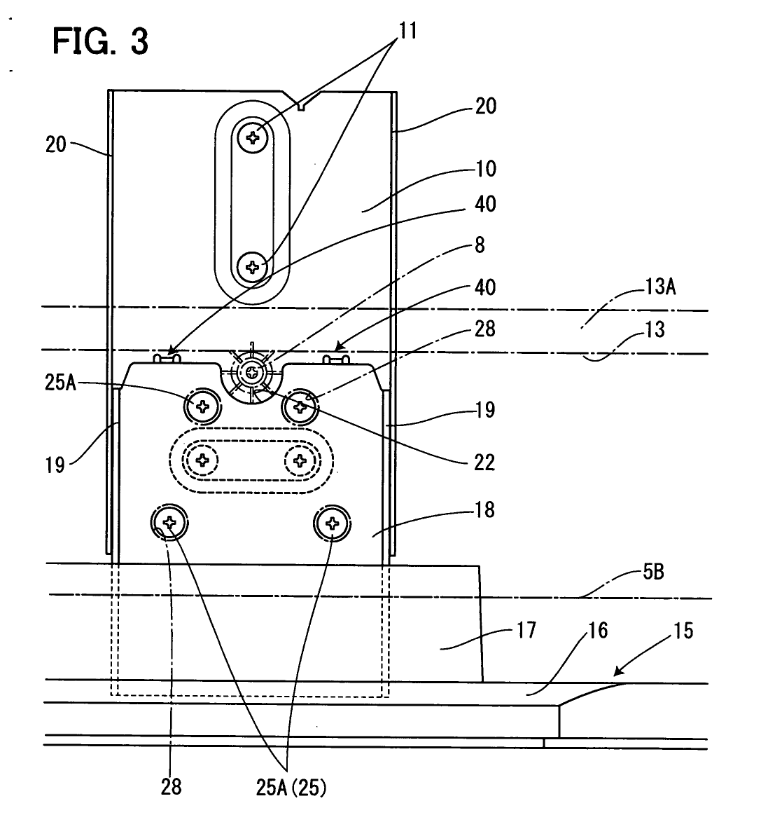

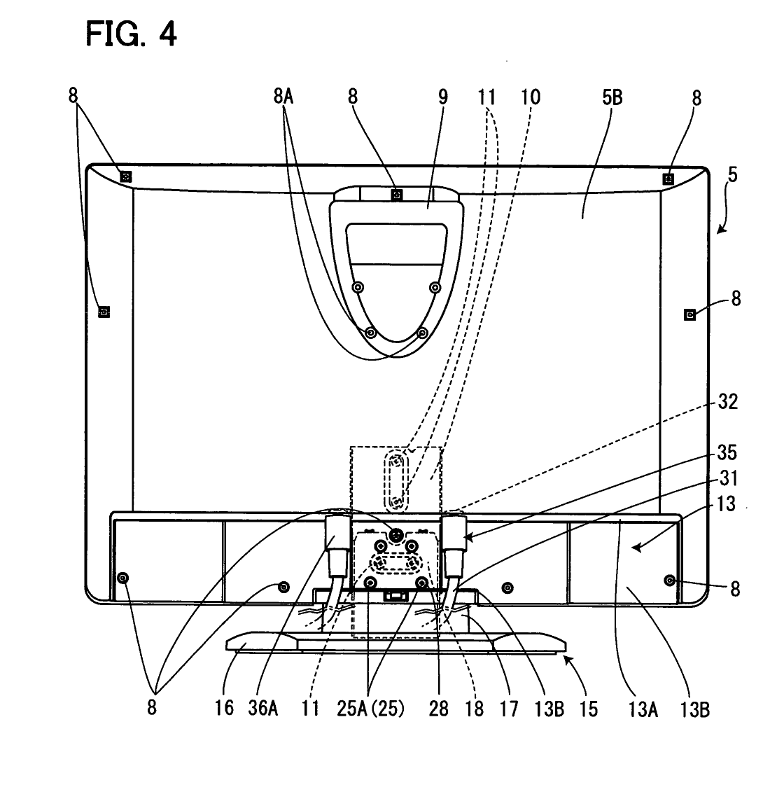

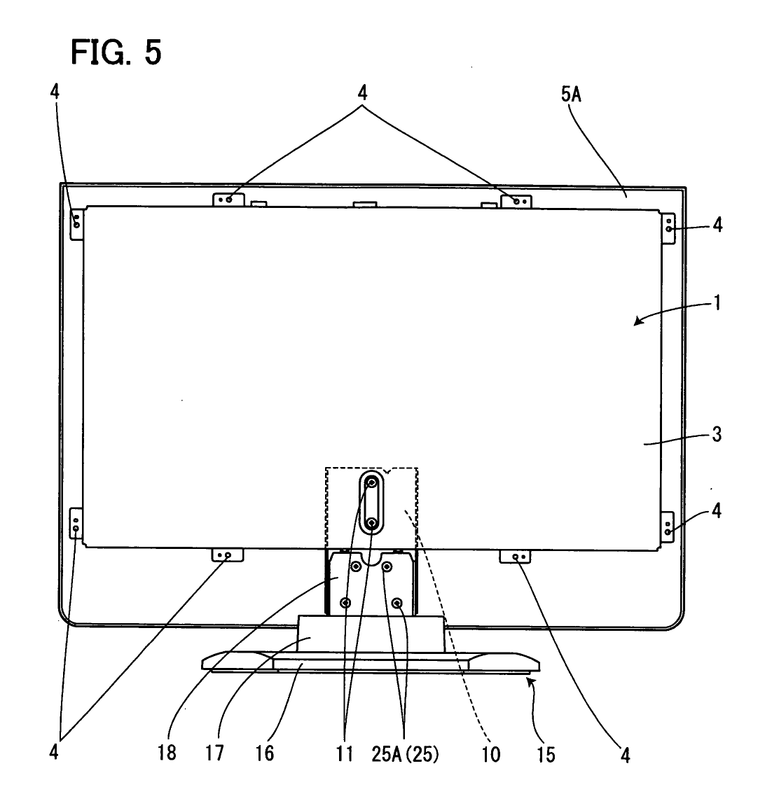

FIGS. 1 to 5 show embodiment 1 of the present invention, FIG. 1 is an enlarged sectional view showing a fixed state of a support bracket showing the embodiment 1 of the present invention, FIG. 2 is an enlarged sectional view showing a fixed state of a mounting bracket, FIG. 3 is a rear view showing a fixed state of the support bracket and the mounting bracket, FIG. 4 is a rear view of a cabinet, and FIG. 5 is a rear view of the cabinet in a state in which a back cabinet is removed. In the drawings, reference numeral 1 denotes a display unit, which is constructed by a liquid crystal panel 2 and a chassis 3 of metal for fixing the liquid crystal panel 2 to a cabinet which will be described later. The above described liquid crystal panel 2 includes a liquid crystal display element body not shown, and a panel fixing frame 2A of metal which covers an outer peripheral side from the rear surface of the liquid crystal display element body, and this panel fixing frame 2A is fixed by a plurality of screws (not shown) to the above described chassis 3. A cabinet 5 which is a casing in which the display unit 1 is incorporated is constituted of a front cabinet 5A and a back cabinet 5B which are separated in front and rear, a display window 6 of the liquid crystal panel 2 is formed at the front cabinet 5A, and this front cabinet 5A and the back cabinet 5B are fixed with a screw 8 as shown in FIG. 4, and a handle 9 is fixed to an upper portion at a center of the back cabinet 5B with screws 8A.

Reference numeral 10 denotes a mounting bracket which is made of a planar metal plate material and is formed into a plate shape as a whole. A lower portion of the mounting bracket 10 is fixed to a center of a lower portion of the chassis 3 by screws 11 so as to project from a lower position of the above described chassis 3, a lower end side of the mounting bracket 10 which projects downward from the above described chassis 3 is fixed with a screw 11A to a mounting boss part 12 integrally formed at the front cabinet 5A. Further, at a lower portion of the above described back cabinet 5B, a stepped recessed part 13, which has an inclined surface 13A inclined downward, which inclines diagonally downward to an inside from the back cabinet 5B, a bottom portion 13B in a planar shape which is connectively provided downward at a lower end portion of the inclined surface 13A, and a cover portion 13C raised from the bottom portion 13B so as to be opposed to the above described inclined surface 13A, is formed, and the bottom portion 13B of the stepped recessed part 13 is fixed to a boss part 21 projectingly provided at the above described front cabinet 5A via the above described mounting bracket 10 with the above described screw 8. As a portion through which the screw 8 is inserted, a recessed part 14 which further projects inward from the stepped recessed part 13 is formed, and a space S into which a later-described support bracket 18 can be inserted is formed between the above described mounting bracket 10 and the bottom portion 13B of the stepped recessed part 13 by the recessed part 14.

Reference numeral 15 is a stand which supports the above described display part 1A, which is constructed by a support base 16, and a hollow support part 17 vertically provided at the support base 16, and the support bracket 18 for fixing the above described mounting bracket 10 is, in the support part 17, pivotally supported to be tiltable in a longitudinal direction by a pivotally support shaft 18A. The support bracket 18 is made of metal similarly to the above described mounting bracket 10, and formed into a plate shape as a whole, and a pair of flange parts 19 are folded at both sides thereof. A pair of guide rails 20 are integrally formed at the above described mounting bracket 10 by folding both sides of the mounting bracket 10 into a flange shape as positioning means for positioning the above described support bracket 18 in a width direction by sandwiching the flange parts 19 of the above described mounting bracket 10 from both sides. Further, as shown in FIG. 3, cut and raised portions 40 are formed at the above described mounting bracket 10, and by butting an upper end edge of the support bracket 18 to the cut and raised portions 40, the support bracket 18 is positioned in the height direction. A semicircular notch 22 for avoiding interference with the above described recessed part 14 is formed at the above described support bracket 18. The mounting bracket 10 and the support bracket 18 are fixed by four fixing screws 25 as fixing members in the state in which the support bracket 18 is positioned with respect to the mounting bracket 10 by the cut and raised portion 40. The fixing screw 25 is screwed into a screw hole 26 formed in the above described mounting bracket 10, an insertion hole 27 through which a screw portion of the fixing screw 25 is inserted is formed in the above described support bracket 18 corresponding to the screw hole 26, and an open hole 28 through which a head portion 25A of the fixing screw 25 can be inserted is formed in the bottom portion 13B of the above described stepped recessed part 13. The above described cover portion 13C of the stepped recessed part 13 is raised from the bottom portion 13B of the stepped recessed part 13 to cover the support part 17 of the stand 15.

A control board 30 which is located between the display unit 2 and the back cabinet 5B to control the display unit 2 is disposed inside the cabinet 5. The control board 30 is fixed with a mounting screw not shown which is formed at the chassis 3 to be parallel with the display unit 2 and the back cabinet 5B which becomes the back surface of the cabinet 5. A connector terminal 32 for connecting to a cable 31 of an external apparatus is mounted to a lower end edge of the control board 30. The connector terminal 32 has its lead terminal 32A bent to correspond to the inclination of the above described inclined surface 13A, and the connector terminal 32 is mounted to the control board 30 mounted substantially vertically in the cabinet 5 to be along the inclination of the inclined surface 13A. As described above, the connector terminal 32 inclined with respect to the control board 30 is fixed to the inclined surface 13A by a mounting frame 34 to face an opening 33 formed in the inclined surface 13A, and a connecting connector 35 provided at the cable 31 is connected to the connector terminal 32 to be connected to an external apparatus (not shown). A housing 36 of the connecting connector 35 in this embodiment is in a straight shape so that the cable 31 continues on the axis of the connecting connector 35, and the cable 31 which is connected to the connecter terminal 32 via the connecting connector 35 continues to the axis of the connecting connector 35 and is drawn out diagonally rearward from the back surface of the cabinet 5 by inclination of the inclined surface 13A, and is led out rearward seen from the back surface side of the cabinet 5. Here, the inclination angle of the inclined surface 13A is set at the angle at which the cable 31 connected to the connector terminal 32 mounted to the inclined surface 13A does not interfere with the cover portion 13C of the stepped recessed part 13 which covers the support column part 17 of the stand 15, and is set at substantially 15 degrees in this embodiment.

The cabinet 5 which houses the display unit 1 and the stand 15 which supports this cabinet 5 are separable, and the cabinet 5 is generally used with the stand 15 mounted thereon as a stationary type, and when used as a wall-hanging type, the handle 9 is removed from the back cabinet 5B by loosening the screw 8A, and the fixing screws 25 are removed from an open hole 28 by loosening the fixing screws 25 by inserting a tool not shown from the open hole 28 formed in the stepped recessed part 13 of the back cabinet 5B to dissemble the cabinet 5 and the stand 15 with the display unit 1 assembled therein, whereby it can be used as a wall-hanging type by hitching the catching hole (not shown) formed in the back cabinet 5B onto a hook or the like provided at the wall surface. The support bracket 18 which fixes the cabinet 5 is pivotally supported at the stand 15 by the pivotally supporting shaft 18A to be slidable in the longitudinal direction, to be capable of adjustment of the angle of the display part 1A fixed to this support bracket 18. Thereby, the display part 1A can be easily adjusted at an angle at which a user can easily see it.

In the embodiment constructed as above, the support bracket 18 fixed to the stand 15 is inserted from the space S between the back cabinet 5B of the cabinet 5 and the mounting bracket 10 to fix the cabinet 5 and the stand 15. At this time, the support bracket 18 is guided by the mounting bracket 10 in the state in which the flange portions 19 folded at both sides of the support bracket 18 along the inner sides of the guide rails 20 formed at both sides of the mounting bracket 10 are positioned in the lateral direction, and with insertion of the support bracket 18, an upper end edge of the support bracket 18 butts to the cut and raised portions 40 formed at the mounting bracket 10 to position the support bracket 18 in the height direction. Thereby, the positions of the open hole 28 formed in the back cabinet 5B, the insertion hole 27 formed in the support bracket 18 and the screw hole 26 of the mounting bracket 10 correspond to one another. The fixing screws 25 are passed through the insertion holes 27 of the support bracket 18 from the open hole 28 of the back cabinet 5B and the fixing screws 25 are screwed into the screw holes 26 of the mounting bracket 10 to fix the mounting bracket 10 and the support bracket 18, whereby the stand 15 is fixed to the cabinet 5.

When the external apparatus is connected to the display unit 1, the connecting connector 35 provided at the cable 31 is connected to the connector terminal 32 mounted to the stepped recessed part 13 of the back cabinet 5B. Since in this case, the connector terminal 32 is mounted along the inclined surface 13A which is formed in a downward direction in the above described stepped recessed part 13 to the control board 30 which is mounted substantially vertically in the cabinet 5, the cable 31 connected to the connector terminal 32 via the connecting connector 35 is drawn out substantially vertically with respect to the inclined surface 13A, and the cable 31 connected to the connector terminal 32 does not interfere with the cover portion 13C of the stepped recessed part 13 which covers the support part 17 of the stand 15. Thereby, the cable 31 can be compactly drawn out without significantly projecting rearward from the back cabinet 5B, and therefore, it is not necessary to secure a useless space for drawing out the cable 31 at the rear side of the back cabinet 5B. Accordingly, space saving is possible, and the angle of the inclined surface 13A is set so that the cable 31 and the cover portion 13C of the stepped recessed part 13 do not interfere with each other. Therefore, stress such as bending stress is not exerted on the joint portion of the connector terminal 32 and the connecting connector 35 and the cable 31.

As described above, in this embodiment, the connector terminal 32 connected to the cable 31 is mounted to the control board 30 by being inclined with respect to the control board 30 which is substantially vertically mounted in the cabinet 5, and the connector terminal 32 is mounted along the inclined surface 13A formed in the downward direction in the stepped recessed part 13 formed at the back cabinet 5B, whereby it is not necessary to secure a useless space for drawing out the cable 31 to the rear side of the back cabinet 5B. In addition, the control board 30 is located between the display unit 2 and the cabinet 5B and fixed to be parallel with the back cabinet 5B, and the connector terminal 32 is mounted to the control board 30 by being inclined with respect to the control board 30, whereby the control board 30 can be compactly mounted in the cabinet 5, and therefore, the cabinet 5 can be made thin. In this manner, the space for drawing out the cable 31 is reduced to be small, and the control board 30 is compactly housed in the cabinet 5, whereby space saving is possible, and in the electronic apparatus which is made thin, especially such as a liquid crystal television receiving set, the advantage of making the apparatus thin can be further enhanced. The cable 31 is drawn out diagonally downward so as not to interfere with the cover portion 13C of the stepped recessed part 13 which functions as the cover portion which covers the support column part 17, and therefore, stress such as bending stress is not exerted on the joint portion of the connector terminal 32 and the connecting connector 35 and the cable 3. By forming the stepped recessed part 13 at the back cabinet 5B, the bottom portion 13B of the stepped recessed part 13 and the mounting bracket 10 are in close vicinity to each other, and when the fixing screw 25 is inserted into the insertion hole 27 of the support bracket 18 and the screw hole 26 of the mounting bracket 10 from the open hole 28 formed in the bottom portion 13B, the positions of the insertion hole 27 and the screw hole 26 can be directly confirmed from the outside of the back cabinet 5B, the fastening operation of the fixing screw 25 is facilitated, and the connecting connector 35 is fixed by utilizing the stepped recessed part 13, whereby it is not necessary to form the mounting part for fitting the connecting connector 35 separately at the back cabinet 5B, and therefore, it is extremely reasonable.

### Embodiment 2

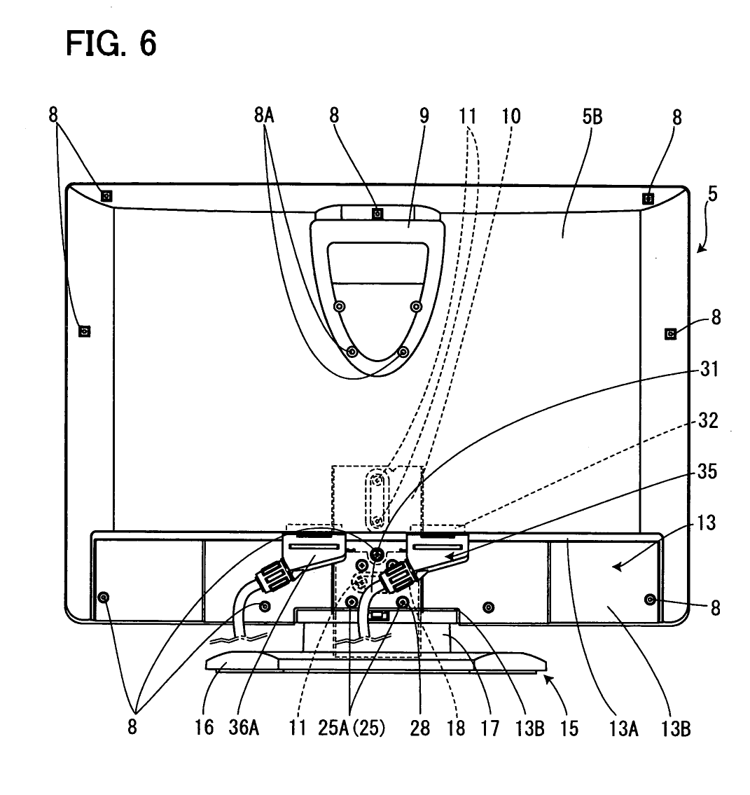

FIG. 6 shows embodiment 2 of the present invention, and the parts in common with the above described embodiment 1 are given the same reference numerals and characters, the explanation of the redundant parts is omitted, and only the different part will be described.

In the above described embodiment 1, the example in which the housing 36A of the connecting connector 35 in this embodiment is in the straight shape so that the cable 31 continues on the axis of the connecting connector 35, but in the embodiment 2, the connector housing 36 of the connecting connector 35 is bent toward an outside so as to guide the cable 31 to the side of the back cabinet 5B. By bending the connector housing 36A of the connecting connector 35 to the outside in this manner, the cable 31 which is connected to the connector terminal 32 via the connecting connector 35 is drawn out diagonally rearward from the back surface of the cabinet 5 by inclination of the inclined surface 13A, and is led out to the side of the cabinet 5 along the connector housing 36A of the connecting connector 35, namely, in this embodiment, to the left side seen from the rear surface side of the cabinet 5 as shown in FIG. 6, and therefore, a routing operation of the cable 31 which is drawn out from the rear surface side of the cabinet 5 is facilitated. Therefore, this embodiment is excellent in operability.

According to an electronic apparatus including a connector terminal according to a first aspect of the present invention, in an electronic apparatus in which various kinds of electronic components and a control board that controls the electronic components are housed inside a casing, a connector terminal connected to the control board is fixed to face an opening formed on a rear surface of the casing, and a connecting connector of an externally connecting cable is connected to the connector terminal, at least an inclined surface with a downward inclination which is formed on the rear surface is included, the opening is formed in the inclined surface, the cable which is connected to the connector terminal fitted to the opening via the connecting connector is guided to be drawn out diagonally rearward in a downward direction, the control board is fixed substantially parallel with respect to the rear surface, and the cable that is connected to the connector terminal mounted to the control board, which is mounted to be inclined with respect to the control board corresponding to an inclination angle of the inclined surface, is drawn out substantially perpendicularly with respect to the inclined surface and is drawn out in the state inclined in the downward direction. Therefore, it is not necessary to secure a useless space to draw out the cable to the rear side of the back cabinet, and it is possible to save the space. Further, with respect to the control board substantially vertically mounted in the casing, the connector terminal for connecting the cable of the external apparatus is mounted to be inclined with respect to the control board to correspond to the inclination angle of the inclined surface formed in the downward direction in the stepped recessed part. Therefore, the control board can be compactly housed in the casing to be able to make the casing thin and to make it unnecessary to secure a useless space for drawing out the cable at the rear side of the back cabinet, and therefore, further space saving is made possible.

According to the electronic apparatus including a connector terminal according to a second aspect, in the electronic apparatus including a connector terminal according to the first aspect, a housing of the connecting connector is bent in a lateral direction so that the cable which is drawn out of the connecting connector is drawn out to a side portion of the casing, whereby the cable which is led out of the connecting connector can be guided to a side of the cabinet, thus facilitating routing of the cable.

According to the electronic apparatus including a connector terminal according to a third or fourth aspect, in the electronic apparatus including a connector terminal according to the first or second aspect, the casing is constituted of a front cabinet and a back cabinet, a display unit is housed in the casing, a stand which supports the casing is provided, a mounting bracket which extends downward is fixed to the display unit, and the mounting bracket is fixed to a support bracket which is rotatably attached to the stand. Therefore, an angle of the display unit is made freely adjustable so as to be an angle at which a viewer easily sees the display unit.

According to the electronic apparatus including a connector terminal according to a fifth or sixth aspect, in the electronic apparatus including a connector terminal according to the third or fourth aspect, a stepped recessed part which includes an inclined surface to which the connector terminal is fitted and a bottom portion is formed at a rear surface of the back cabinet, and a cover portion which covers the stand is provided extensively from the bottom portion of the stepped recessed part to be opposed to the inclined surface, and the inclination angle of the inclined surface is set so that the cable drawn out of the inclined surface does not interfere with the cover portion. Therefore, the cable can be drawn out without exerting stress such as bending stress on a joint portion of the connector terminal and the connecting connector and the cable.

According to the electronic apparatus including a connector terminal according to a seventh, eighth, ninth or tenth aspect, in the electronic apparatus including a connector terminal according to the third, fourth, fifth or sixth aspect, a space in which the support bracket is capable of being inserted is formed between the mounting bracket and the bottom portion of the stepped recessed part, the mounting bracket and the support bracket are fixed with a screw, and an open hole through which the fixing screw is capable of being inserted is formed at the bottom portion of the stepped recessed part. Therefore, when the fixing screw which fixes the support bracket and the mounting bracket is inserted from the open hole formed at the bottom portion of the stepped recessed part, the positions of the insertion hole formed in the mounting bracket, through which the fixing screws are inserted and the screw holes formed in the support bracket can be easily recognized from the outer surface side of the back cabinet, and a fastening operation of the fixing screws is facilitated.

What is claimed is:

1. An electronic apparatus including a connector terminal, in which various kinds of electronic components and a control board that controls the electronic components are housed inside a casing, a connector terminal connected to the control board is fixed to face an opening formed on a rear surface of the casing, and a connecting connector of an externally connecting cable is connected to the connector terminal, comprising:
at least an inclined surface with a downward inclination, which is formed on the rear surface,
wherein the opening is formed in the inclined surface, the cable which is connected to the connector terminal fitted to the opening via the connecting connector is guided to be drawn out diagonally rearward in a downward direction, the control board is fixed substantially parallel with respect to the rear surface, and the connector terminal which is mounted to the control board is mounted to be inclined with respect to the control board corresponding to an inclination angle of the inclined surface.

2. The electronic apparatus including a connector terminal according to claim 1, wherein a housing of the connecting connector is bent in a lateral direction so that the cable which is drawn out of the connecting connector is drawn out to a side portion of the casing.

3. The electronic apparatus including a connector terminal according to claim 1,
wherein the casing is constituted of a front cabinet and a back cabinet, a display unit is housed in the casing, a stand which supports the casing is provided, a mounting bracket which extends downward is fixed to the display unit, and the mounting bracket is fixed to a support bracket which is rotatably attached to the stand.

4. The electronic apparatus including a connector terminal according to claim 2,
wherein the casing is constituted of a front cabinet and a back cabinet, a display unit is housed in the casing, a stand which supports the casing is provided, a mounting bracket which extends downward is fixed to the display unit, and the mounting bracket is fixed to a support bracket which is rotatably attached to the stand.

5. The electronic apparatus including a connector terminal according to claim 3,
wherein a stepped recessed part which includes an inclined surface to which the connector terminal is fitted and a bottom portion is formed at a rear surface of the back cabinet, and a cover portion which covers the stand is provided extensively from the bottom portion of the stepped recessed part to be opposed to the inclined surface, and the inclination angle of the inclined surface is set so that the cable drawn out of the inclined surface does not interfere with the cover portion.

6. The electronic apparatus including a connector terminal according to claim 4,
wherein a stepped recessed part which includes an inclined surface to which the connector terminal is fitted and a bottom portion is formed at a rear surface of the back cabinet, and a cover portion which covers the stand is provided extensively from the bottom portion of the stepped recessed part to be opposed to the inclined surface, and the inclination angle of the inclined surface is set so that the cable drawn out of the inclined surface does not interfere with the cover portion.

7. The electronic apparatus including a connector terminal according to claim 3,
wherein a space in which the support bracket is capable of being inserted is formed between the mounting bracket and the bottom portion of the stepped recessed part, the mounting bracket and the support bracket are fixed with a screw, and an open hole through which the fixing screw is capable of inserted is formed at the bottom portion of the stepped recessed part.

8. The electronic apparatus including a connector terminal according to claim 4,
wherein a space in which the support bracket is capable of being inserted is formed between the mounting bracket and the bottom portion of the stepped recessed part, the mounting bracket and the support bracket are fixed with a screw, and an open hole through which the fixing screw is capable of inserted is formed at the bottom portion of the stepped recessed part.

9. The electronic apparatus including a connector terminal according to claim 5,
wherein a space in which the support bracket is capable of being inserted is formed between the mounting bracket and the bottom portion of the stepped recessed part, the mounting bracket and the support bracket are fixed with a screw, and an open hole through which the fixing screw is capable of inserted is formed at the bottom portion of the stepped recessed part.

10. The electronic apparatus including a connector terminal according to claim 6,
wherein a space in which the support bracket is capable of being inserted is formed between the mounting bracket and the bottom portion of the stepped recessed part, the mounting bracket and the support bracket are fixed with a screw, and an open hole through which the fixing screw is capable of inserted is formed at the bottom portion of the stepped recessed part.
